(19) United States
(12) Patent Application Publication
(10) Pub. No.: US 2025/0105074 A1
(43) Pub. Date: Mar. 27, 2025

(54) GLASS CORES INCLUDING PROTRUDING THROUGH GLASS VIAS AND RELATED METHODS

(71) Applicant: Intel Corporation, Santa Clara, CA (US)

(72) Inventors: Bohan Shan, Chandler, AZ (US); Haobo Chen, Chandler, AZ (US); Wei Wei, Chandler, AZ (US); Jose Fernando Waimin Almendares, Gilbert, AZ (US); Ryan Joseph Carrazzone, Chandler, AZ (US); Kyle Jordan Arrington, Gilbert, AZ (US); Ziyin Lin, Chandler, AZ (US); Dingying Xu, Chandler, AZ (US); Hongxia Feng, Chandler, AZ (US); Yiqun Bai, Chandler, AZ (US); Hiroki Tanaka, Gilbert, AZ (US); Brandon Christian Marin, Gilbert, AZ (US); Jeremy Ecton, Gilbert, AZ (US); Benjamin Taylor Duong, Phoenix, AZ (US); Gang Duan, Chandler, AZ (US); Srinivas Venkata Ramanuja Pietambaram, Chandler, AZ (US); Rui Zhang, Chandler, AZ (US); Mohit Gupta, Chandler, AZ (US)

(73) Assignee: Intel Corporation, Santa Clara, CA (US)

(21) Appl. No.: 18/977,572

(22) Filed: Dec. 11, 2024

(51) Int. Cl. H01L 23/15; H01L 23/00; H01L 23/13; H01L 23/498

(52) U.S. Cl. CPC H01L 23/15; H01L 23/13; H01L 23/49822; H01L 23/49838; H01L 24/14; H01L 24/16; H01L 2224/1403; H01L 2224/16227; H01L 2924/16152

(57) ABSTRACT

Glass cores including protruding through glass vias and related methods are disclosed herein. An example substrate disclosed herein includes a glass core including a surface and a copper through glass via (TGV) extending through the glass core, the TGV including a protrusion extending from the surface.

### BACKGROUND

Integrated circuit (IC) chips and/or semiconductor dies are routinely connected to larger circuit boards such as motherboards and other types of printed circuit boards (PCBs) via a package substrate. As IC chips and/or dies reduce in size and interconnect densities increase, alternatives to traditional substrate layers are being developed to provide stable transmission of high-frequency data signals between different circuitry and/or increased power delivery. One option being pursued is the implementation of package substrates with glass cores.

### BRIEF DESCRIPTION OF THE DRAWINGS

FIG. 1 is a cross-sectional side view of an example integrated circuit (IC) package constructed in accordance with teachings disclosed herein.

FIG. 2 illustrates a prior substrate core that experienced a seware failure.

FIG. 3 is cross-sectional side view of an example first package substrate that can be used in conjunction with the integrated circuit package of FIG. 1.

FIGS. 4A, 4B, 4C, and 4D illustrate different intermediate stages in an example fabrication process to manufacture the substrate core of FIG. 3.

FIG. 5 is a flowchart representative of an example method that may be performed to fabricate the first substrate core of FIG. 3 via the intermediate stages of FIGS. 4A-4D.

FIG. 6 is cross-sectional side view of an example second package substrate that can be used in conjunction with the integrated circuit package of FIG. 1.

FIGS. 7A, 7B, 7C, and 7D illustrate different intermediate stages in an example fabrication process to manufacture the substrate core of FIG. 6.

FIG. 8 is a flowchart representative of an example method that may be performed to fabricate the second substrate core of FIG. 6 via the intermediate stages of FIGS. 7A-7D.

FIG. 9 is a top view of a wafer including dies that may be included in an IC package constructed in accordance with teachings disclosed herein.

FIG. 10 is a cross-sectional side view of an IC device that may be included in an IC package constructed in accordance with teachings disclosed herein.

FIG. 11 is a cross-sectional side view of an IC device assembly that may include an IC package constructed in accordance with teachings disclosed herein.

FIG. 12 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

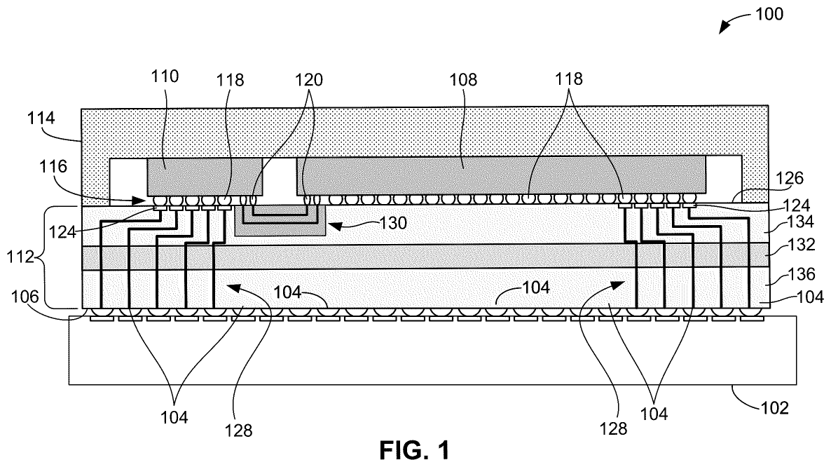

FIG. 1 illustrates an example integrated circuit package 100 constructed in accordance with teachings disclosed herein. In the illustrated example, the IC package 100 is electrically coupled to an underlying substrate 102 via an array of contacts 104 on a package mounting surface 106 (e.g., a bottom surface, an external surface) of the package. In some examples, the substrate 102 can be implemented by a package substrate or a printed circuit board (PCB). In the illustrated example, the contacts 104 are represented as balls. However, in some examples, the IC package 100 may include pads, lands, and/or any other type of contact, in addition to or instead of the pads or lands shown to enable the electrical coupling of the IC package 100 to the substrate 102. In this example, the IC package 100 includes two dies 108, 110 (e.g., silicon dies, semiconductor dies, etc.), sometimes also referred to as chips or chiplets, that are mounted to a package substrate 112 and enclosed by a package lid 114 (e.g., a mold compound, an integrated heat spreader (IHS)). Thus, the package substrate 112 is an example means for supporting a semiconductor die. While the example IC package 100 of FIG. 1 includes two dies 108, 110, in other examples, the IC package 100 may have only one die or more than two dies. In some examples, one of the dies 108, 110 (or a separate die) is embedded in the package substrate 112. The dies 108, 110 can provide any suitable type of functionality (e.g., data processing, memory storage, etc.). In some examples, one or both of the dies 108, 110 are implemented by a die package including multiple dies arranged in a stacked formation. For example, the second die 110 can include a stack of Dynamic Random Access Memory (DRAM) die arranged on top of a memory controller die to form a memory die stack.

As shown in the illustrated example, each of the dies 108, 110 is electrically and mechanically coupled to the package substrate 112 via corresponding arrays of interconnects 116. In FIG. 1, the interconnects are shown as bumps. The interconnects 116 can include solder joints, micro bumps, combinations of metallic (e.g., copper) pillars and solder, etc. In other examples, the interconnects 116 may include directly bonded or “hybrid bonded” metallic interconnects. In other examples, the interconnects 116 may be any other type of electrical connection in addition to or instead of the bumps shown (e.g., balls, pins, pads, pillars, wire bonding, etc.). The electrical connections between the dies 108, 110 and the package substrate 112 (e.g., the interconnects 116) are sometimes referred to as first level interconnects. By contrast, the electrical connections between the IC package 100 and the substrate 102 (e.g., the contacts 104) are sometimes referred to as second level interconnects. In some examples, one or both of the dies 108, 110 may be stacked on top of one or more other dies and/or an interposer. In such examples, the dies 108, 110 are coupled to the underlying die and/or interposer through a first set of first level interconnects and the underlying die and/or interposer may be connected to the package substrate 112 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 116 of the first level interconnects include two different types of bumps corresponding to core bumps 118 and bridge bumps 120. As used herein, the core bumps 118 are bumps on the dies 108, 110 through which electrical signals pass between the dies 108, 110 and components external to the IC package 100. More particularly, as shown in the illustrated example, when the dies 108, 110 are mounted to the package substrate 112, the core bumps 118 are physically connected and electrically coupled to contact pads 124 on a die mounting surface 126 (e.g., an upper surface, a top surface, etc.) of the package substrate 112. The contact pads 124 on the die mounting surface 126 of the package substrate 112 are electrically coupled to the contacts 104 on the package mounting surface 106 (e.g., the bottom, external surface) of the package substrate 112 (e.g., a surface opposite the die mounting surface 126) via internal interconnects 128 within the package substrate 112. As a result, there is a continuous electrical signal path between the core bumps 118 of the dies 108, 110 and the contacts 104 mounted to the substrate 102 that pass through the contact pads 124 and the internal interconnects 128 provided therebetween. As shown, the package mounting surface 106 and the die mounting surface 126 define opposing outer surfaces of the package substrate 112. While both surfaces are outer surfaces of the package substrate, the die mounting surface 126 is sometimes referred to herein as an internal or inner surface relative to the IC package 100. By contrast, in this example, the package mounting surface 106 is an outer or exterior surface of the IC package 100.

As used herein, the bridge bumps 120 are bumps on the dies 108, 110 through which electrical signals pass between different ones of the dies 108, 110 within the IC package 100. Thus, as shown in the illustrated example, the bridge bumps 120 of the first die 108 are electrically coupled to the bridge bumps 120 of the second die 110 via an interconnect bridge 130 (e.g., a silicon-based interconnect bridge, an interconnect die, an embedded interconnect bridge (EMIB)) embedded in the package substrate 112. As represented in FIG. 1, core bumps 118 are typically larger than bridge bumps 120. In some examples, interconnect bridge 130 and the associated bridge bumps 120 are omitted.

In some examples, the IC package 100 includes additional passive components, such as surface-mount resistors, capacitors, and/or inductors disposed on the package mounting surface 106 of the package substrate 112 and/or the die mounting surface 126 of the package substrate 112.

In FIG. 1, the package substrate 112 of the example IC package 100 includes a glass core 132 (e.g., a glass substrate, a glass layer, etc.) between two separate build-up regions 134, 136 (also referred to herein as build-up layers, etc.). In some examples, the glass core 132 includes at least one of: aluminosilicate, borosilicate, alumino-borosilicate, silica, and/or fused silica. In some examples, the glass core 132 includes one or more additives including: aluminum oxide (Al₂O₃), boron trioxide (B₂O₃), magnesia oxide (MgO), calcium oxide (CaO), stoichiometric silicon oxide (SrO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, the glass core 132 includes silicon and oxygen. In some examples, the glass core 132 includes silicon, oxygen and/or one or more of aluminum, boron, magnesium, calcium, barium, tin, sodium, potassium, strontium, phosphorus, zirconium, lithium, titanium, and/or zinc. In some examples, the glass core 132 includes at least 23 percent silicon by weight and at least 26 percent oxygen by weight. In some examples, the glass core is a layer of glass including silicon, oxygen, and aluminum. In some examples, the glass core 132 includes at least 23 percent silicon by weight, at least 26 percent oxygen by weight, and at least 5 percent aluminum by weight.

In some examples, the glass core 132 is an amorphous solid glass layer. In some examples, the glass core 132 is a layer of glass that does not include an organic adhesive or an organic material. In some examples, the glass core 132 is a solid layer of glass having a rectangular shape in plan view. In some examples, the glass core 132, as a glass substrate, includes at least one glass layer and does not include epoxy and does not include glass fibers (e.g., does not include an epoxy-based prepreg layer with glass cloth). In some examples, the glass core 132 corresponds to a single piece of glass that extends the full height/thickness of the core. In other examples, the glass core 132 can be silicon, a dielectric material, and/or any other material(s).

In some examples, the glass core 132 has a rectangular shape that is substantially coextensive (e.g., within 10%), in plan view, with the layers above and/or below the core. In some examples, the glass core 132 has a thickness in a range of about 50 micrometers (μm) to about 1.4 millimeters (mm). In some examples, the glass core 132 can be a multi-layer glass substrate (e.g., a coreless substrate), where a glass layer has a thickness in a range of about 25 μm to about 50 μm. In some examples, the glass core 132 can have dimensions of about 10 mm on a side to about 250 mm on a side (e.g., 10 mm by 10 mm to 250 mm by 250 mm). In some examples, the glass core 132 corresponds to a rectangular prism volume with sections (e.g., vias) removed and filled with other materials (e.g., metal). Among other things, glass cores are advantageous over epoxy-based cores because glass is stiffer and, therefore, provides greater mechanical support or strength for the package substrate. Thus, the glass core 132 is an example means for strengthening the package substrate.

The build-up regions 134, 136 are represented in FIG. 1 as masses/blocks with the internal interconnects 128 extending in straight lines through the build-up regions 134, 136 (and the glass core 132). However, FIG. 1 has been simplified for the sake of clarity and purposes of explanation. In practice, the interconnects are not necessarily straight. More particularly, in some examples, the build-up regions 134, 136 are defined by alternating layers of dielectric material and layers of conductive material (e.g., a metal such as copper). The conductive (metal) layers serve as the basis for the internal interconnects 128 represented, in a simplified form, by straight lines as shown in FIG. 1. In some examples, the metal layers are patterned to define electrical routing or conductive traces that are electrically coupled between different metal layers by conductive (e.g., metal) vias extending through intervening dielectric layers.

Using glass as a starting core material (e.g., the glass core 132 of FIG. 1) has a mechanical benefit (e.g., reduced warpage, smaller thickness variation), an electrical benefit, and a design flexibility benefit (e.g., tighter through-hole pitch, finer core routing) over using traditional organic core materials (e.g., epoxy-based prepreg). For example, the glass core 132 can support multi-chip packaging (e.g., embedded multi-die interconnect bridge (EMIB), 2.5D/3D heterogeneous integration, hyper chip stacking (silicon (Si) interposers), etc.), reduced first level interconnect (FLI) bump pitches (e.g., less than 30 micrometer (μm)), reduced fine line spacing (FLS) (e.g., 2/2 μm), higher density interconnects, higher input/output (I/O) density patterning, increasing form factors, and decreasing package thicknesses over the traditional organic core materials. To further facilitate these advantages, the glass core 132 can include through-glass vias (TGVs) (e.g., copper-plated vias) extending through the glass core 132 to electrically couple the build-up region 134 to the build-up region 136. While examples described herein are described with reference to the glass core 132, it should be appreciated that teachings of this disclosure are not limited thereto. For example, the teachings of this disclosure are also applicable to organic cores.

A common type of failure of known glass cores is referred to as a seware failure. Seware failures result in the separation of a glass core along a crack that propagates from an edge of the glass core along its length and width between the main outer surfaces (e.g., upper and lower surfaces, front and back surfaces) of the glass core. That is, seware failures are characterized by a glass core being split into two separate sheets of glass along a line extending generally parallel to the main plane of the glass core.

Factors that contribute to seware failures include mismatches in coefficient of thermal expansion (CTE) between different components of a glass core and features mounted thereon. For example, the glass of the core (e.g., the glass core 132, etc.), the metal (e.g., copper, etc.) of the TGVs extending therethrough, and the organic dielectric material of the build-up layers (e.g., the build-up layers 130, etc.) deposited thereon can have CTE. Generally, the material in the build-up regions has a higher CTE than glass and the material of the TGVs has a higher CTE than the material of the build-up regions. As a result, the material in the build-up regions and the material of the TGVs expands and contracts more than the glass core in response to thermal fluctuations, thereby causing thermal internal stress within the glass core that can promote crack propagation.

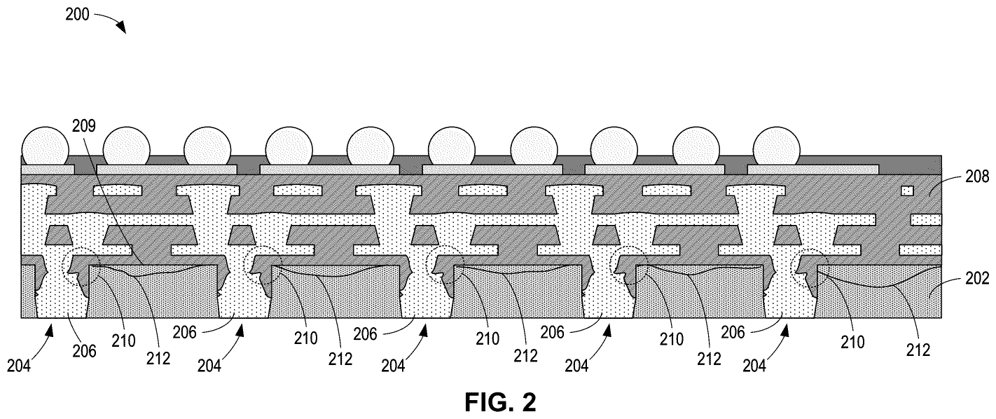

FIG. 2 illustrates a cross-sectional side view of a prior package substrate 200 undergoing a seware failure. In FIG. 2, the package substrate 200 includes a glass core 202, a plurality of through holes 204, a plurality of TGVs 206 deposited in the through holes 204, and a build-up material 208. One source of CTE mismatch-induced thermal stress is associated with the plating of the metal of the TGVs 206. During the electroplating of the TGVs 206, metal is electroplated into the through holes 204 of the glass core 202 and the first surface 209 thereof. After the electroplating of the TGVs 206, a first surface 209 of the glass core 202 is etched to remove the metal deposited thereon. However, the etching of the metal on the glass core 202 can remove metal at the entrance of the through holes 204. When the build-up material 208 is subsequently deposited on the first surface 209 of the glass core 202, some of the build-up material 208 enters the openings in the through holes 204 formed by the etching of the copper on the first surface 209. The resulting lateral stacks 210 of metal, organic dielectric material, and glass in the through hole of the TGV are stress concentration locations (e.g., a weak point, etc.) and can cause acute stress thermal concentrations at the entry of the through holes 204. That is, the layering of materials in the lateral stacks 210 can cause high amounts of thermal-induced stress when the package substrate is subject to temperature fluctuations, such as those associated with the manufacturing and/or operation of the package substrate 200. In FIG. 2, the stress concentration associated with the lateral stacks 210 has caused the formation of seware cracks 212 in the glass core 202 between the TGVs 206.

Examples disclosed herein reduce (e.g., minimize, etc.) concern for seware failures in the glass cores of package substrates. Examples disclosed herein include glass cores with TGVs that protrude from the top and bottom surfaces of the glass core. An example fabrication process disclosed herein includes a multi-operation etching process that includes applying a copper wet etch, a plasma dry etch, and a sulfuric acid wet etch to the outer surfaces of the glass core. In some examples disclosed herein, glass cores include a plurality of curved surfaces extending between the TGVs. Another example fabrication process disclosed herein includes a two-operation polishing process that includes a copper chemical mechanical polishing and a silicon chemical mechanical polishing. Examples disclosed herein prevent the deposition of the buffer material within the throughs holes of TGVs, which reduces the thermal-induced stress experienced by the glass cores of package substrates and improves the durability thereof.

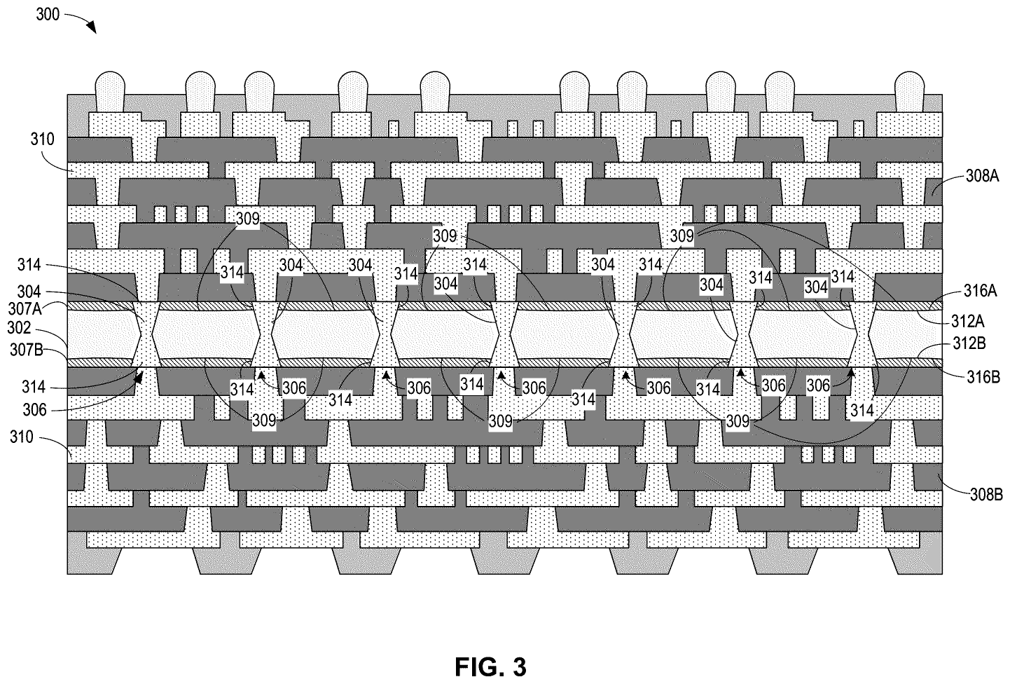

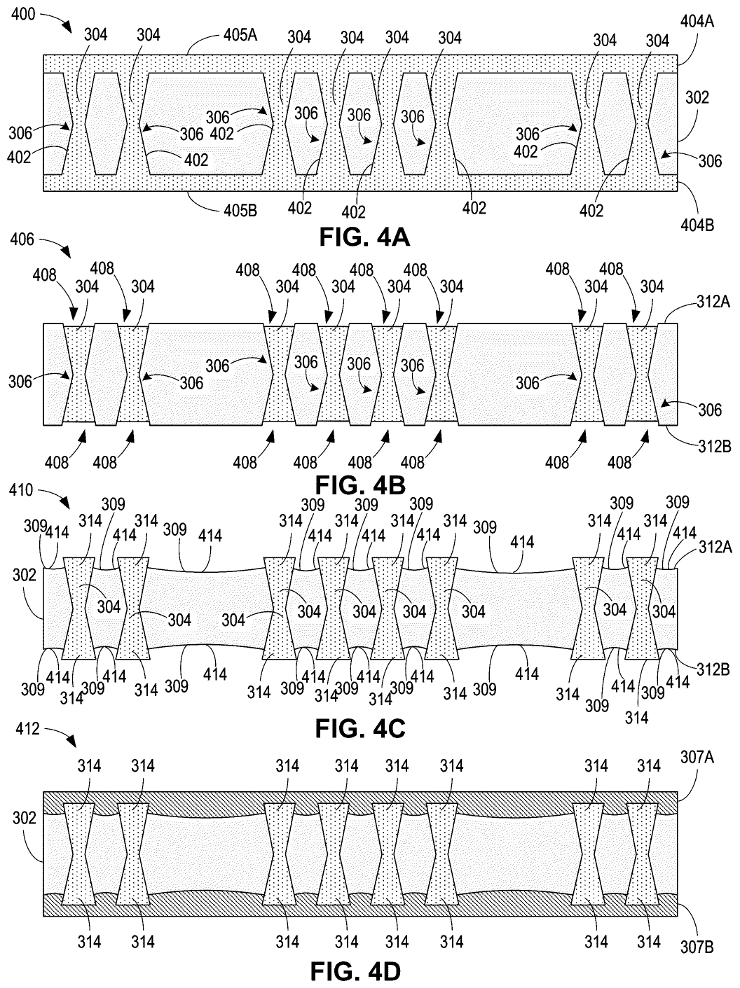

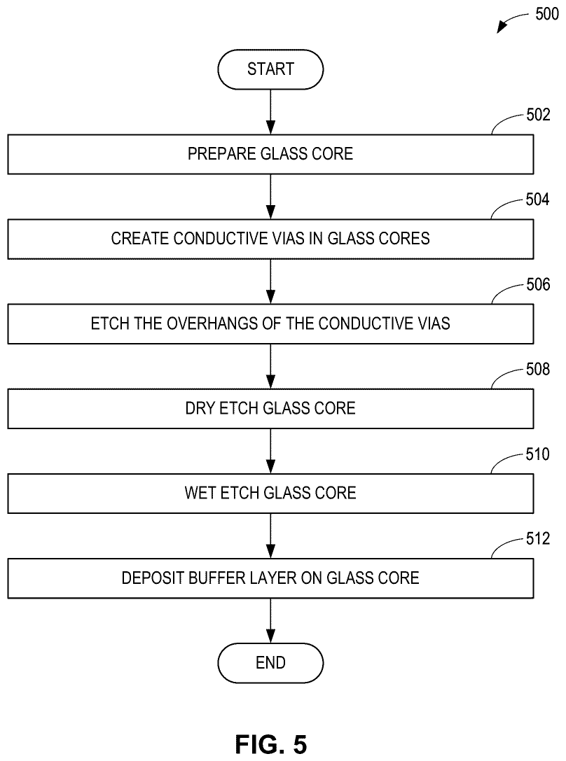

FIG. 3 is a cross-sectional side view of an example first package substrate 300 that can implement the package substrate 112 of FIG. 1. In the illustrated example of FIG. 3, the first package substrate 300 includes an example first glass core 302, an example plurality of TGVs 304 in an example corresponding plurality of openings 306, an example first buffer layer 307A, an example second buffer layer 307B, an example first build-up layer 308A, and an example second build-up layer 308B. In the illustrated example of FIG. 3, the first glass core 302 includes an example plurality of regions 309, which are disposed between the TGVs 304. In the illustrated example of FIG. 3, the build-up layers 308A, 308B include an example plurality of interconnects 310, which extend therethrough. In the illustrated example of FIG. 3, the first glass core 302 includes an example first surface 312A and an example second surface 312B. In the illustrated example of FIG. 3, the TGVs 304 include example protrusions 314, which extend from the first glass core 302. An example first process to manufacture the first package substrate 300 of FIG. 3 via etching and the intermediate stages of manufacture associated therewith are described below in conjunction with FIGS. 4A-5

The first glass core 302 corresponds to the glass core 132 of FIG. 1. In the illustrated example of FIG. 3, the first glass core 302 supports and is disposed between the buffer layers 307A, 307B and the build-up layers 308A, 308B. The build-up layers 308A, 308B correspond to the build-up regions 134, 136 of FIG. 1. In the illustrated example of FIG. 3, the build-up layers 308A, 308B include interconnects 310, which are electrically coupled to the plurality of TGVs 304. In some examples, the build-up layers 308A, 308B can be redistribution layers. In some examples, the interconnects 310 are electrically coupled to components mounted on the package substrate 300 (e.g., the dies 108, 110 of FIG. 1, etc.) and electrically couple the TGVs 304 thereto.

In the illustrated example of FIG. 3, the buffer layers 307A, 307B are disposed on the first surface 312A and the second surface 312B, respectively. In the illustrated example of FIG. 3, the buffer layers 307A, 307B are between the build-up layers 308A, 308B, respectively, and the glass core 302. In the illustrated example of FIG. 3, the buffer layers 307A, 307B include (e.g., contain, are composed of, etc.) a dielectric material (e.g., an organic epoxy, an Ajinomoto build-up film (ABF), etc.). In some examples, the buffer layers 307A, 307B facilitate the adhesion of the build-up layers 308A, 308B to the first glass core 302 due to the poor adhesion of the metal of the interconnects 310 to the first glass core 302. In some examples, the buffer layers 307A, 307B facilitate the distribution of stress (e.g., buffer stress, etc.) between the glass core 302, the TGVs 304, and the build-up layers 308A, 308B. In the illustrated example of FIG. 3, the buffer layers 307A, 307B at least partially surround (e.g., circumfuse, encompass, partially enclose, enclose, etc.) the protrusions 314 of the TGVs 304 (e.g., the first buffer layer 307A surrounds the protrusions 314 extending from the first surface 312A, the second buffer 307B surrounds the protrusions 314 extending from the second surface 312B, etc.). In the illustrated example of FIG. 3, the buffer layers 307A, 307B surround the sides of the protrusions 314. Additionally or alternatively, the buffer layers 307A, 307B surround the outer surfaces of the protrusions 314. In some examples, the buffer layers 307A, 307B are absent. In some such examples, the build-up layers 308A, 308B surround and/or encompass the protrusions 314 of the TGVs 304.

The plurality of regions 309 of the first glass core 302 are the portions of the glass core 202 that extend between individual ones of the TGVs 304. In the illustrated example of FIG. 3, the first glass core 302 has a concave curvature in the plurality of regions 309 (e.g., has a deflection toward the interior of the first glass core 302, etc.). That is, each of the plurality of regions 309 has a curved shape. It should be appreciated that the first glass core 302 is a 3-dimensional component, which extends into and out of the page of FIG. 3. In some such examples, the plurality of regions 309 includes curvature(s) that extends into and out of the page of FIG. 3. In some such examples, each of the plurality of regions 309 is shaped generally like a meniscus. In some examples, the curvature of the plurality of regions 309 is formed via the wet etching of the first glass core 302 during the manufacturing thereof. The curvature of plurality of regions 309 and the formation thereof is described in additional detail in conjunction with FIG. 4D.

In the illustrated example of FIG. 3, in the plurality of regions 309, the thickness of the first glass core 302 is proportional to the distance from each of the TGVs 304 (e.g., the first glass core 302 has a comparatively greater thickness adjacent to the TGVs 304 and a comparatively lesser thickness distal to the TGVs 304, etc.). In the illustrated example of FIG. 3, the TGVs 304 abut (e.g., are in contact with, directly contact, etc.) the first glass core 302 at the surfaces 312A, 312B and/or the plurality of regions 309. That is, in each of the plurality of regions 309, the first glass core 302 is thicker in areas adjacent to the TGVs 304 and thinner in areas distal to the TGVs 304.

In the illustrated example of FIG. 3, the protrusions 314 are the ends of the TGVs 304. In the illustrated example of FIG. 3, the protrusions 314 of the TGVs 304 extend from the surfaces 312A, 312B of the first glass core 302. That is, the protrusions 314 are not flush with the surfaces 312A, 312B and instead are displaced outward from corresponding regions 309 of the first glass core 302. In the illustrated example of FIG. 3, the TGVs 304 protrude from both the first surface 312A and the second surface 312B (e.g., some of the protrusions 314 extend above the first surface 312A, some of the protrusions 314 extend below the second surface 312B, etc.). In other examples, the TGVs 304 protrude from one of the first surface 312A or the second surface 312B (e.g., one of the surfaces 312A, 312B is flush with the ends of the TGVs, etc.).

In the illustrated example of FIG. 3, each of the protrusions 314 is integral (e.g., monolithic with, etc.) and continuous (e.g., not discrete, etc.) with the corresponding one of the TGVs 304. For example, the protrusions 314 and the other portions of the TGVs 304 are deposited during the same process (e.g., the electroplating of the TGVs 304 into the openings 306, etc.) and thus, form one or more unitary pieces. In some examples, the protrusions 314 are formed via the removal of material from adjacent portions of the first glass core 302 (e.g., the protrusions 314 are formed during the etching of the first glass core 302 that causes the ends of the TGVs 304 to protrude from the first glass core 302, etc.). In some examples, the protrusions 314 protrude from the surfaces 312A, 312B with a thickness of between 5% and 20% of the total thickness of the first glass core 302. In some examples, the protrusions 314 have a length above the surface of the first glass core 302 between approximately 5 and approximately 20 microns long. The protrusions 314 of the TGVs 304 prevent material of the buffer layers 307A, 307B and/or the build-up layers 308A, 308B from entering the openings 306 during the deposition thereof, which prevents the formation of a lateral stack of materials with different CTEs (e.g., a lateral stack similar to the lateral stack 210 of FIG. 2, etc.) and the associated increased risk of seware failure.

In the illustrated example of FIG. 3, the buffer layers 307A, 307B include an example first buffer layer surface 316A and an example second buffer layer surface 316B, respectively. In the illustrated example of FIG. 3, the buffer layer surfaces 316A, 316B abut (e.g., directly contact, etc.) the outer surfaces 312A, 312B and are complimentary thereto. The buffer layer surfaces 316A, 316B have a curvature that is complimentary to the curvature of the outer surfaces 312A, 312B.

FIGS. 4A, 4B, 4C, and 4D illustrate different intermediate stages in an example first process to manufacture the first glass core 302 of FIG. 3. Example operations to manufacture the first glass core 302 of FIG. 3 involve some or all of the intermediate stages of FIGS. 4A-4D are described below in conjunction with FIG. 5. In some examples, prior to example first intermediate stage 400 of FIG. 4A, the openings 306 are created in the first glass core 302. For example, the openings 306 can be formed in the first glass core 302 via a laser-induced deep etching (LIDE) process. In other examples, the openings 306 can be formed via a mechanical process, such as drilling.

FIG. 4A is a cross-sectional schematic view of an example first intermediate stage 400 of the assembly/manufacturing of the first glass core 302 of FIG. 3. During the first intermediate stage 400, the TGVs 304 of FIG. 3 can be deposited in the openings 306 via electroplating. For example, the TGVs 304 can be electroplated into the openings 306 via a preliminary seed layer deposited on example internal surfaces 402 of the openings 306. In some examples, the preliminary seed layer can be deposited via an electrolysis process. In other examples, the preliminary seed layer can be deposited via a different process (e.g., lithography, a thin-film deposition process, etc.). In other examples, the TGVs 304 can be electroplated from one of the top or bottom of the first glass core 302. Additionally or alternatively, the TGVs 304 can be deposited in another other suitable manner (e.g., lithography, etc.).

In the illustrated example of FIG. 4A, the electroplating of the TGVs 304 causes an example first overhang 404A and an example second overhang 404B to be deposited on the surfaces 312A, 312B, respectively. The overhangs 404A, 404B are conductive layers associated with the deposition of excess material during the formation of the TGVs 304. In the illustrated example of FIG. 4A, the overhangs 404A, 404B are integral with and extend from the TGVs 304. In some examples, one of the overhangs 404A, 404B is absent (e.g., the TGVs 304 are flush with the first surface 312A or the second surface 312B, etc.). In the illustrated example of FIG. 4A, the overhangs 404A, 404B are electrically coupled to and materially integral with each of the TGVs 304. In the illustrated example of FIG. 4A, the overhangs 404A, 404B include an example first outer overhang surface 405A and an example second outer overhang surface 405B, respectively.

FIG. 4B is a cross-sectional schematic view of an example second intermediate stage 406 of the assembly/manufacturing of the first glass core 302 of FIG. 3. In some examples, the second intermediate stage 406 can occur after the first intermediate stage 400 of FIG. 4A. During the second intermediate stage 406, the overhangs 404A, 404B on the surfaces 312A, 312B are etched via wet etching. For example, the surfaces 312A, 312B are wet etched to remove the overhangs 404A, 404B. For example, an etching solution (e.g., a solution of nitric acid, a solution of iron chloride, a solution of hydrogen peroxide and sulfuric acid, a solution of cupric chloride, etc.) can be applied to the outer overhang surfaces 405A, 405B of FIG. 4A. In some examples, the etching solution is selected to not be reactive with the glass of the first glass core 302. In the illustrated example of FIG. 4B, the etching of the copper on the surfaces 312A, 312B causes the formation of example recesses 408 into the openings 306 of FIG. 3. That is, in the illustrated example of FIG. 4B, the TGVs 304 are thinner than the first glass core 302. In the illustrated example of 4B, the recesses 408 cause the TGVs 304 to not be flush with the surfaces 312A, 312B.

FIG. 4C is a cross-sectional schematic view of an example third intermediate stage 410 of the assembly/manufacturing of the first glass core 302 of FIG. 3. In some examples, the third intermediate stage 410 can occur after the first intermediate stage 400 of FIG. 4A. During the third intermediate stage 410, the surfaces 312A, 312B of the first glass core 302 are dry etched. For example, the surfaces 312A, 312B can be plasma etched. In some such examples, the surfaces 312A, 312B are plasma etched via carbon tetrafluoride (CF₄), carbon tetrachloride (CCl₄), sulfur hexafluoride (SF6), xenon difluoride (XeF2), and/or one or more other plasma carbon fluorides, etc. In some examples, the reaction of the etching plasma and the glass of the glass core near the surfaces 312A, 312B causes portions of the first glass core 302 to react therewith and form a gas, such as a silicon fluoride and/or a silicon chloride, etc. In some examples, the dry etching medium is selected to not be reactive with copper (e.g., the copper of the TGVs 304 is not reactive with the dry etching medium, etc.). In other examples, the surfaces 312A, 312B can be etched via a different drying etching technique.

The dry etching weakens the portions of the first glass core 302 near the surfaces 312A, 312B. After the application of the dry etching medium, the surfaces 312A, 312B are wet etched (e.g., acid etched, acid washed, etc.) via the application of sulfuric acid (H₂SO₄). In other examples, the surfaces 312A, 312B can be wet etched via a different medium (e.g., a different acid, etc.). In some examples, the weakened glasses near the surfaces 312A, 312B is removed by (e.g., washed away, dissolved into, etc.) the applied cleaning medium. In some examples, the cleaning medium applied to the surfaces 312A, 312B is selected to not affect the copper of the TGVs 304.

In the illustrated example of FIG. 4C, the copper of the TGVs 304 is not affected and/or is minorly affected (e.g., not significantly etched, not significantly removed, etc.) by the etching associated with the intermediate stage 410 of FIG. 4C. Because the conductive material (e.g., the copper, etc.) of the TGVs 304 is not removed by the etching, the exposure of the first glass core 302 to the etching mediums is proportional to the distance from the TGVs 304. The increased exposure of the glass core 302 near the center of the plurality of regions 309 causes the glass of the first glass core 302 to be removed unevenly (e.g., comparatively less material is removed from the surfaces 312A, 312B near the TGVs 304, comparatively more material is removed from the surfaces 312A, 312B near the TGVs 304, etc.). In the illustrated example of FIG. 4C, the uneven removal of material from the surfaces 312A, 312B of the first glass core 302 causes the plurality of regions 309 to have example curved surfaces 414. In the cross-sectional view of the illustrated example of FIG. 4C, the curved surfaces 414 are generally parabolically shaped. In the illustrated example of FIG. 4C, each of the curved surfaces 414 is concave (e.g., the surfaces 414 curved curve toward the center of the glass core 302, etc.).

In other examples, the curved surfaces 414 can have any other curvature profile (e.g., hyperbolic, a different polynomial, trigonometric, circular, etc.). It should be appreciated that the curved surfaces 414 are three-dimensional and include can curvatures profiles, which extend into and out of the page. In some such examples, the curved surfaces 414 are generally meniscus-shaped. In the illustrated example of FIG. 4C, the etching of the first glass core 302 and the removal of material therefrom causes the protrusions 314 of FIG. 3 of the TGVs 304 to extend from the curved surfaces 414 of the first glass core 302.

FIG. 4D is a cross-sectional schematic view of an example fourth intermediate stage 412 of the assembly/manufacturing of the first glass core 302 of FIG. 3. In some examples, the fourth intermediate stage 412 can occur after the third intermediate stage 410 of FIG. 4B. During the fourth intermediate stage 412, the buffer layers 307A, 307B are deposited on the first surface 312A and the second surface 312B of the first glass core 302. For example, the buffer layers 307A, 307B can be deposited via lamination, a thin-film deposition method, and/or other suitable deposition method (e.g., CVD, ALD, etc.).

FIG. 5 is a flowchart representative of an example method 500 that may be performed to fabricate any one of the example first package substrate 300 of FIG. 3 via the intermediate stages 400, 406, 410, 412 of FIGS. 4A-4D. In some examples, some or all of the operations outlined in the example method of FIG. 5 are performed automatically by equipment that is programmed to perform the operations. That is, in some examples, the example method or portions thereof may be implemented and/or controlled by one or more processor circuits executing instructions based on data from sensors and/or user inputs. Although the example method is described with reference to the flowchart illustrated in FIG. 5, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 5 begins at block 502, at which the first glass core 302 is prepared. In some examples, the first glass core 302 can be prepared by casting a glass mixture in a planar shape. In other examples, the first glass core 302 can be prepared in any other suitable manner. In some examples, the first glass core 302 is created with the openings 306. In some examples, the first glass core 302 can be positioned in a fabrication environment. At block 504, the TGVs 304 are created in the first glass core 302. For example, the TGVs 304 can be deposited in the openings 306 via electroplating. In some examples, the TGVs 304 can be electroplated into the openings 306 via a preliminary seed layer deposited on the internal surfaces 402 of FIG. 4A. In some examples, the preliminary seed layer can be deposited via an electrolysis process. In other examples, the preliminary seed layer can be deposited via a different process (e.g., lithography, a thin-film deposition process, etc.). In other examples, the TGVs 304 can be electroplated from one of the surfaces 312A, 312B. Additionally or alternatively, the TGVs 304 can be deposited in another other suitable manner (e.g., lithography, etc.). In some examples, the creation of the TGVs 304 causes the formation of the overhangs 404A, 404B on the surfaces of the first glass core 302 (e.g., the surfaces 312A, 312B, etc.). The point of fabrication after completion of block 504 corresponds to the structure of the first intermediate stage 400 of FIG. 4A.

At block 506, the overhangs 404A, 404B of the TGVs 304 are etched. For example, the overhangs 404A, 404B on the surfaces 312A, 312B can be etched via wet etching. For example, the outer overhang surfaces 405A, 405B are etched via copper etching to remove the overhangs 404A, 404B. In the illustrated example of FIG. 4B, the etching of the copper on the outer overhang surfaces 405A, 405B causes the formation of example recesses 408 into the openings 306 of FIG. 3. In the illustrated example, the recesses 408 causes the TGVs 304 to not be flush with the surfaces 312A, 312B. The point of fabrication after completion of block 506 corresponds to the structure of the second intermediate stage 406 of FIG. 4B.

At block 508, the first glass core 302 is plasma etched. For example, the surfaces 312A, 312B can be plasma etched. For example, the surfaces 312A, 312B can be plasma etched via carbon tetrafluoride (CF₄), carbon tetrachloride (CCl₄), sulfur hexafluoride (SF6), xenon difluoride (XeF2), and/or other plasma carbon fluorides, etc. In some examples, the reaction of the etching medium and the glass of the glass core near the surfaces 312A, 312B causes portions of the first glass core 302 to react therewith and form a gas, such as a silicon fluoride and/or a silicon chloride, etc. In some examples, the dry etching medium is selected to not be reactive with copper (e.g., the copper of the TGVs 304 is not reactive with the dry etching medium, etc.). In other examples, the surfaces 312A, 312B can be etched via a drying etching technique. In some examples, the dry etching weakens the portions of the first glass core 302 near the surfaces 312A, 312B. The point of fabrication after completion of block 508 corresponds to the structure of the third intermediate stage 410 of FIG. 4C.

At block 510, the first glass core 302 is wet etched. For example, the surfaces 312A, 312B of the first glass core 302 are wet etched. For example, the surfaces 312A, 312B can be wet etched via sulfuric acid (H₂SO₄). In other examples, the surfaces 312A, 312B can be wet etched via a different medium (e.g., a different acid, etc.). In some examples, the weakened glasses near the surfaces 312A, 312B is removed (e.g., washed away, dissolved into, etc.) by the wet etching medium. In some examples, the wet etching medium applied to the surfaces 312A, 312B is selected to not affect the copper of the TGVs 304. The point of fabrication after completion of block 510 corresponds to the structure of the third intermediate stage 410 of FIG. 4C.

At block 512, the buffer layers 307A, 307B are deposited on the surfaces 312A, 312B. For example, the buffer layers 307A, 307B can be deposited via lamination, a thin-film deposition method, and/or other suitable deposition method (e.g., CVD, ALD, etc.). The point of fabrication after completion of block 512 corresponds to the structure of the fourth intermediate stage 412 of FIG. 4D. The method 500 end. Thereafter, the completed substrate core may undergo any suitable subsequent processing (e.g., adding build-up layers, attaching one or more dies, and implementing other packaging processes).

Although example operations are described with reference to the flowchart illustrated in FIG. 5, many other methods of assembling/manufacturing the first glass core 302 of FIG. 3 may alternatively be used. For example, the order of execution of the blocks may be changed, and/or some of the blocks described may be changed, eliminated, or combined.

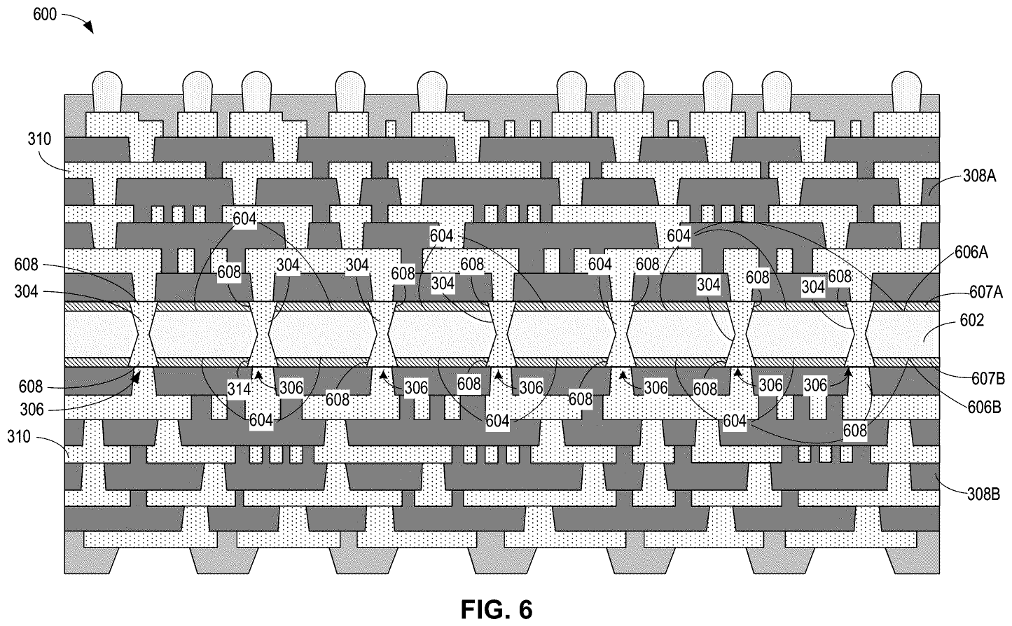

FIG. 6 is a cross-sectional side view of an example second package substrate 600 that can implement the package substrate 112 of FIG. 1. The second package substrate 600 is similar to the first package substrate of FIG. 3, except as noted otherwise. In the illustrated example of FIG. 6, the second package substrate 600 includes an example second glass core 602, which includes the plurality of openings 306 of FIG. 3. In the illustrated example of FIG. 6, the second glass core 602 includes the plurality TGVs 304 of FIG. 3 in corresponding ones of the plurality of openings 306 of FIG. 3, the build-up layers 308A, 308B of FIG. 3, and the interconnects 310 of FIG. 3. In the illustrated example of FIG. 6, the second glass core 602 includes an example plurality of regions 604, which extend between the TGVs 304. In the illustrated example of FIG. 6, the second glass core 602 includes an example first surface 606A and an example second surface 606B.

In the illustrated example of FIG. 6, the outer surfaces 606A, 606B of the plurality of regions 604 of the second glass core 602 are substantially planar (e.g., not curved, flat, etc.). That is, the outer surfaces 606A, 606B of the second glass core 602 are parallel to and recessed from the top of the TGVs 304. In the illustrated example of FIG. 6, each of the plurality of regions 604 is coplanar. In other examples, the plurality of regions 604 are not coplanar (e.g., some of the plurality of regions 604 are recessed from other ones of the plurality of regions 604, etc.). In the illustrated example of FIG. 6, the TGVs 304 abut (e.g., are in contact with, directly contact, etc.) the second glass core 602 at the surfaces 606A, 606B, and/or the plurality of regions 604.

In the illustrated example of FIG. 6, the second package substrate 600 includes an example first buffer layer 607A and an example second buffer layer 607B. The buffers layers 607A, 607B are similar to the buffer layers 307A, 307B of FIG. 3, except that the buffer layers 607A, 607B have a planar surface geometry adjacent to the outer surfaces 606A, 606B (e.g., the buffer layers 607A, 607B have a shape corresponding to and complimentary to the outer surfaces 606A, 606B, etc.). In the illustrated example of FIG. 6, the buffer layers 607A, 607B surround (e.g., encompass, partially enclose, etc.) the protrusions 314 of the TGVs 304 (e.g., the first buffer layer 607A surrounds the protrusions 314 extending from the first surface 606A, the second buffer layer 607B surrounds the protrusions 314 extending from the second surface 606B, etc.).

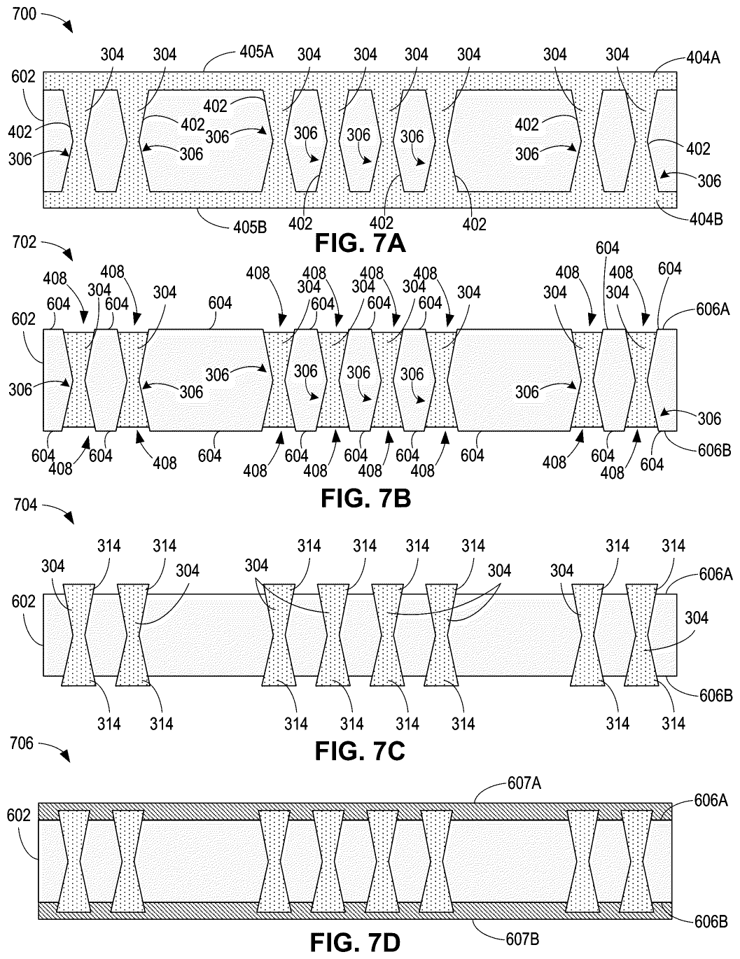

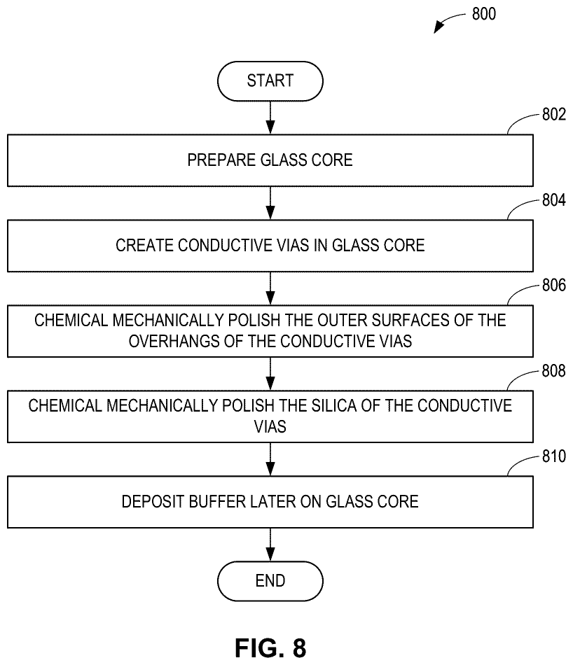

In the illustrated example of FIG. 6, the TGVs 304 include protrusions 608, which are similar to the protrusions 314 of FIG. 3 except as noted otherwise. In the illustrated example of FIG. 6, the protrusions 314 of the TGVs 304 extend from the outer surfaces 606A, 606B of the second glass core 602. That is, the protrusions 608 are not flush with the outer surfaces 606A, 606B and displaced outward (e.g., protrude, etc.) from the plurality of regions 604 of the second glass core 602. In the illustrated example of FIG. 6, the TGVs 304 protrude from both the first surface 606A and the second outer surface 606B of the second glass core 602. In other examples, the TGVs 304 protrude from one of the first surface 606A or the second outer surface 606B of the second glass core 602. In some examples, the protrusions 608 protrude from the outer surfaces 606A, 606B with a thickness of between 5% and 20% of the total thickness of the second glass core 602. In some examples, the protrusions 608 are between 5 and 20 microns long. The protrusions 608 of the TGVs 304 prevent material of the buffer layers 607A, 607B and/or the build-up layers 308A, 308B from entering the through openings 306 during the deposition thereof, which prevents the formation of a lateral stack of materials with different CTEs (e.g., a lateral stack similar to the lateral stack 210 of FIG. 2, etc.). An example second process to manufacture the second package substrate 600 of FIG. 6 via chemical-mechanical polishing and the intermediate stages of manufacture associated therewith are described below in conjunction with FIGS. 7A-8.

FIGS. 7A, 7B, 7C, and 7D illustrate different intermediate stages in an example second fabrication process to manufacture the second package substrate 600 of FIG. 6. Example operations to manufacture the second package substrate 600 of FIG. 6 involve some or all of the intermediate stages of FIGS. 7A-7D are described below in conjunction with FIG. 7. In some examples, prior to example first intermediate stage 400 of FIG. 4A, the second glass core 602 is prepared in a manner similar to the preliminary process applied to the first glass core 302 before the first intermediate stage 400 described in conjunction with FIG. 4A.

FIG. 7A is a cross-sectional schematic view of an example first intermediate stage 700 of the assembly/manufacturing of the second glass core 602 of FIG. 6. During the first intermediate stage 700, the TGVs 304 of FIG. 3 can be deposited in the openings 306 via electroplating. For example, the TGVs 304 can be electroplated in a manner similar to the deposition of the TGVs 304 described in conjunction with the first intermediate stage 400 of FIG. 7A. In the illustrated example of FIG. 7A, the deposition of the TGVs 304 forms the overhangs 404A, 404B of FIG. 4A, which have the corresponding outer overhang surfaces 405A, 405B of FIG. 4A.

FIG. 7B is a cross-sectional schematic view of an example second intermediate stage 702 of the assembly/manufacturing of the second glass core 602 of FIG. 6. In some examples, the second intermediate stage 702 can occur after the first intermediate stage 700 of FIG. 7A. During the illustrated example of FIG. 7B, the outer overhang surfaces 405A, 405B of the glass core are polished via a first chemical mechanical polishing (CMP) process. In the illustrated example of FIG. 7B, the first CMP process applied to the outer overhang surfaces 405A, 405B causes the formation of example recesses 408 into the openings 306 (e.g., the first CMP process causes the TGVs 304 to be recessed from the outer surfaces 606A, 606B, etc.). In other examples, the first CMP process causes the tops and/or bottoms of the TGVs 304 to be flush with the outer surfaces 606A, 606B (e.g., the recesses 408 are absent, etc.).

In some examples, during the second intermediate stage 702, the outer overhang surfaces 405A, 405B are polished with a medium (e.g., a CMP slurry, etc.) that is selected to remove the copper of the overhangs 404A, 404B and the TGVs 304 (e.g., copper, etc.) at a faster rate than the glass of the second glass core 602 (e.g., a copper specific slurry, etc.). For example, an alumina (AlO₃) and/or a silica (SiO₂) slurry can be used to abrade and oxidize the copper of the overhangs 404A, 404B (e.g., oxidize into a copper oxide, oxidized into a copper chloride, etc.) and is not hard enough to significantly degrade the glass of the second glass core 602. In some examples, the medium includes chemicals (e.g., ammonium chloride, copper sulfate, ammonium sulfate, etc.) that etches and/or oxides the copper of the overhangs 404A, 404B. In some examples, after the application of the CMP medium, the outer overhang surfaces 405A, 405B can be treated with an acid and/or other solvent to remove the oxidized copper. In the illustrated example of FIG. 7A, the chemical mechanical polishing of the outer surfaces 606A, 606B removes the overhangs 404A, 404B and a portion of the TGVs 304 within the openings 306. In other examples, the outer overhang surfaces 405A, 405B of the overhangs 404A, 404B are polished until the copper of the TGVs 304 is flush with the outer surfaces 606A, 606B.

FIG. 7C is a cross-sectional schematic view of an example third intermediate stage 704 of the assembly/manufacturing of the first glass core 302 of FIG. 3. In some examples, the third intermediate stage 704 can occur after the second intermediate stage 702 of FIG. 7B. During the third intermediate stage 704, the outer surfaces 606A, 606B of the second glass core 602 are polished via a second chemical mechanical polishing (CMP) process. In some examples, the outer surfaces 606A, 606B can be polished with a medium (e.g., a CMP slurry, etc.) that is selected to remove the glass of the second glass core 602 at a faster rate than the conductive material of the TGVs 304 (e.g., a glass/oxide specific slurry). For example, a cerium (Ce) based slurry, such as ceria oxide (CeO₂), can be selected to abrade the glass of the second glass core 602.

In the illustrated example of FIG. 7C, the application of the second CMP process to the outer surfaces 606A, 606B of the second glass core 602 and the corresponding removal of material therefrom, causes the recession of the plurality of regions 604. In the illustrated example of FIG. 7C, after the second CMP, the protrusions 314 of the TGVs 304 extend from the outer surfaces 606A, 606B.

FIG. 7D is a cross-sectional schematic view of an example fourth intermediate stage 706 of the assembly/manufacturing of the second glass core 602 of FIG. 6. In some examples, the fourth intermediate stage 706 can occur after the third intermediate stage 704 of FIG. 7C. During the fourth intermediate stage 706, the buffer layers 607A, 607B are deposited on the first outer surface 606A and the second outer surface 606B of the second glass core 602. For example, the buffer layers 607A, 607B can be deposited in a manner similar to the deposition of the buffer layers 307A, 307B described in conjunction with the fourth intermediate stage 412 of FIG. 4D.

FIG. 8 is a flowchart representative of an example second method 800 that may be performed to fabricate the example second package substrate 600 of FIG. 6 via the intermediate stages 700, 702, 704 of FIGS. 7A-7C. In some examples, some or all of the operations outlined in the example method of FIG. 8 are performed automatically by equipment that is programmed to perform the operations. That is, in some examples, the example method or portions thereof may be implemented and/or controlled by one or more processor circuits executing instructions based on data from sensors and/or user inputs. Although the example method is described with reference to the flowchart illustrated in FIG. 8, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 8 begins at block 802, at which the second glass core 602 is prepared. In some examples, the second glass core 602 can be prepared by casting a glass mixture in a planar shape. In other examples, the second glass core 602 can be prepared in any other suitable manner. In some examples, the second glass core 602 can be positioned in a fabrication environment. At block 804, the TGVs 304 are formed in the second glass core 602. For example, the TGVs 304 can be deposited in the second glass core 602 via the operations described in conjunction with block 504 of FIG. 5. In other examples, the TGVs 304 can be deposited in any other suitable manner. In some examples, the formation of the TGVs 304 causes the overhangs 404A, 404B to be deposited on the outer surfaces 606A, 606B. The point of fabrication after completion of block 804 corresponds to the structure of the first intermediate stage 700 of FIG. 7A.

At block 806, the outer overhang surfaces 405A, 405B of the overhangs 404A, 404B are polished via a first chemical mechanical polishing (CMP) process. In some examples, the outer overhang surfaces 405A, 405B can be polished with a medium (e.g., a CMP slurry, etc.) that is selected to remove the copper of the overhangs 404A, 404B and the TGVs 304 (e.g., copper, etc.). For example, an alumina and/or silica-based slurry can be used to abrade and oxidize the copper of the overhangs 404A, 404B (e.g., oxidize into a copper oxide, oxidized into a copper chloride, etc.). In some examples, the medium of the first chemical mechanical polishing process is selected to remove the conductive material (e.g., copper, etc.) of the TGVs 304 and not the glass (e.g., silica, etc.) of the second glass core 602. In some examples, after the application of the medium, the outer overhang surfaces 405A, 405B can be treated with an acid and/or other solvent to remove the oxidized copper. In some examples, the chemical mechanical polishing of the surfaces 312A, 312B removes the overhangs 404A, 404B and a portion of the TGVs 304 within the openings 306. In other examples, the outer overhang surfaces 405A, 405B of the overhangs 404A, 404B are polished until the copper of the TGVs 304 is flush with the outer surfaces 606A, 606B. The point of fabrication after completion of block 806 corresponds to the structure of the second intermediate stage 702 of FIG. 7B.

At block 808, the outer surfaces 606A, 606B of the second glass core 602 are polished via a second CMP process. In some examples, the outer surfaces 606A, 606B can be polished with a medium (e.g., a CMP slurry, etc.) that is selected to remove the glass of the second glass core 602 and not the conductive material of the TGVs 304. For example, cerium (Ce) based slurry, such as ceria oxide (CeO₂), can be selected to abrade the glass of the second glass core 602. At block 810, the buffer layers 307A, 307B are deposited on the outer surfaces 606A, 606B. For example, the buffer layers 307A, 307B can be deposited via the operations described in conjunction with block 512 of FIG. 5. The point of fabrication after completion of block 810 corresponds to the structure of the fourth intermediate stage 706 of FIG. 7D. The method 800 ends. Thereafter, the completed substrate core may undergo any suitable subsequent processing (e.g., adding build-up layers, attaching one or more dies, and implementing other packaging processes). Although example operations are described with reference to the flowchart illustrated in FIG. 8, many other methods of assembling/manufacturing the second package substrate 600 of FIG. 6 may alternatively be used. For example, the order of execution of the blocks may be changed, and/or some of the blocks described may be changed, eliminated, or combined.

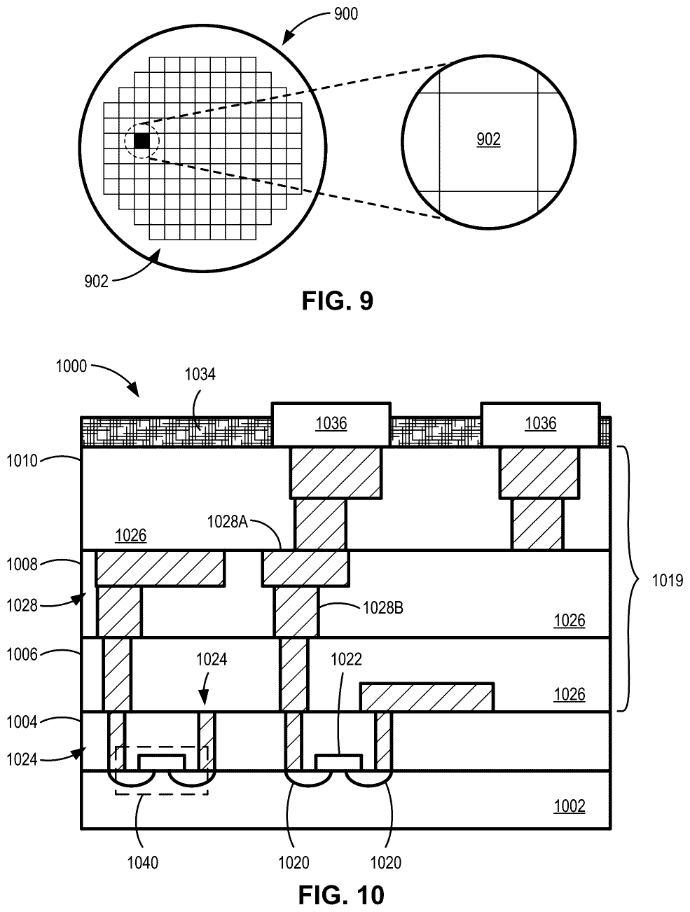

The example IC package 100 of FIG. 1 (e.g., with the first package substrate 300, with the second package substrate 600, etc.) disclosed herein may be included in any suitable electronic component. FIGS. 9-12 illustrate various examples of apparatus that may include or be included in the IC package 100 disclosed herein.

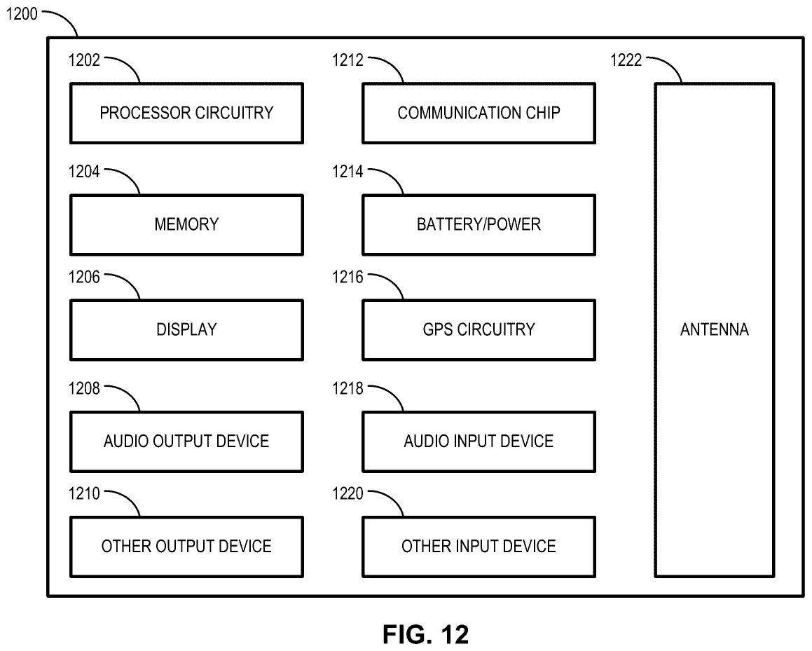

FIG. 9 is a top view of a wafer 900 and dies 902 that may be included in the IC package 100 of FIG. 1 (e.g., as any suitable ones of the dies 108, 110). The wafer 900 includes semiconductor material and one or more dies 902 having circuitry. Each of the dies 902 may be a repeating unit of a semiconductor product. After the fabrication of the semiconductor product is complete, the wafer 900 may undergo a singulation process in which the dies 902 are separated from one another to provide discrete “chips.” The die 902 includes one or more transistors (e.g., some of the transistors 1040 of FIG. 10, discussed below), supporting circuitry to route electrical signals to the transistors, passive components (e.g., traces, resistors, capacitors, inductors, and/or other circuitry), and/or any other components. In some examples, the die 902 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die (e.g., the die 902, etc.). For example, a memory array of multiple memory circuits may be formed on a same (e.g., the die 902, etc.) as programmable circuitry (e.g., the processor circuitry 1202 of FIG. 12) and/or other logic circuitry. Such memory may store information for use by the programmable circuitry. The example IC package 100 disclosed herein may be manufactured using a die-to-wafer assembly technique in which some dies are attached to a wafer 900 that includes others of the dies, and the wafer 900 is subsequently singulated.

FIG. 10 is a cross-sectional side view of an IC device 1100 that may be included in the example IC package 100 (e.g., in any one of the dies 108, 110). One or more of the IC devices 1000 may be included in one or more dies 902 (FIG. 9). The IC device 1000 may be formed on a die substrate 1002 (e.g., the wafer 900 of FIG. 9) and may be included in a die (e.g., the die 902 of FIG. 9). The die substrate 1002 may be a semiconductor substrate including semiconductor materials including, for example, n-type or p-type materials systems (or a combination of both). The die substrate 1002 may include, for example, a crystalline substrate formed using a bulk silicon or a silicon-on-insulator (SOI) substructure. In some examples, the die substrate 1002 may be formed using alternative materials, which may or may not be combined with silicon, which include but are not limited to germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an IC device 1000 may be used. The die substrate 1002 may be part of a singulated die (e.g., the dies 902 of FIG. 9) or a wafer (e.g., the wafer 900 of FIG. 9).

The IC device 1000 may include one or more device layers 1004 disposed on and/or above the die substrate 1002. The device layer 1004 may include features of one or more transistors 1040 (e.g., metal oxide semiconductor field-effect transistors (MOSFETs)) formed on the die substrate 1002. The device layer 1004 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1040 may include a gate 1022 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1040 along the source-channel-drain direction, the gate electrode may include a U-shaped structure that includes a bottom portion substantially parallel to the surface of the die substrate 1002 and two sidewall portions that are substantially perpendicular to the first surface of the die substrate 1002. In other examples, at least one of the metal layers that form the gate electrode may be a planar layer that is substantially parallel to the first surface of the die substrate 1002 and does not include sidewall portions substantially perpendicular to the first surface of the die substrate 1002. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of corresponding transistor(s) 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1020 may be formed using one or more alternate semiconductor materials such as germanium or a group III-V material or alloy. In further examples, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the IC device 1000.

The interconnect structures 1028 may be arranged within the interconnect layers 1006-1010 to route electrical signals according to a wide variety of designs (in particular, the arrangement is not limited to the particular configuration of interconnect structures 1028 depicted in FIG. 10). Although a particular number of interconnect layers 1006-1010 is depicted in FIG. 10, examples of the present disclosure include IC devices having more or fewer interconnect layers than depicted.

In some examples, the interconnect structures 1028 may include lines 1028A and/or vias 1028B filled with an electrically conductive material such as a metal. The lines 1028A may be arranged to route electrical signals in a direction of a plane that is substantially parallel with a surface of the die substrate 1002 upon which the device layer 1004 is formed. For example, the lines 1028A may route electrical signals in a direction in and/or out of the page from the perspective of FIG. 10. The vias 1028B may be arranged to route electrical signals in a direction of a plane that is substantially perpendicular to the surface of the die substrate 1002 upon which the device layer 1004 is formed. In some examples, the vias 1028B may electrically couple lines 1028A of different interconnect layers 1006-1010 together.

The interconnect layers 1006-1010 may include a dielectric material 1026 disposed between the interconnect structures 1028, as shown in FIG. 10. In some examples, the dielectric material 1026 disposed between the interconnect structures 1028 in different ones of the interconnect layers 1006-1010 may have different compositions; in other examples, the composition of the dielectric material 1026 between different interconnect layers 1006-1010 may be the same.

A first interconnect layer 1006 (referred to as Metal 1 or “M1”) may be formed directly on the device layer 1004. In some examples, the first interconnect layer 1006 may include lines 1028A and/or vias 1028B, as shown. The lines 1028A of the first interconnect layer 1006 may be coupled with contacts (e.g., the S/D contacts 1024) of the device layer 1004.

A second interconnect layer 1008 (referred to as Metal 2 or “M2”) may be formed directly on the first interconnect layer 1006. In some examples, the second interconnect layer 1008 may include vias 1028B to couple the lines 1028A of the second interconnect layer 1008 with the lines 1028A of the first interconnect layer 1006. Although the lines 1028A and the vias 1028B are structurally delineated with a line within each interconnect layer (e.g., within the second interconnect layer 1008) for the sake of clarity, the lines 1028A and the vias 1028B may be structurally and/or materially contiguous (e.g., simultaneously filled during a dual-damascene process) in some examples.

A third interconnect layer 1010 (referred to as Metal 3 or “M3”) (and additional interconnect layers, as desired) may be formed in succession on the second interconnect layer 1008 according to similar techniques and/or configurations described in connection with the second interconnect layer 1008 or the first interconnect layer 1006. In some examples, the interconnect layers that are “higher up” in the metallization stack 1019 in the IC device 1000 (i.e., further away from the device layer 1004) may be thicker.

The IC device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to other external devices. For example, solder bonds may be formed on the one or more conductive contacts 1036 to mechanically and/or electrically couple a chip including the IC device 1000 with another component (e.g., a circuit board). The IC device 1000 may include additional or alternate structures to route the electrical signals from the interconnect layers 1006-1010; for example, the conductive contacts 1036 may include other analogous features (e.g., posts) that route the electrical signals to external components.

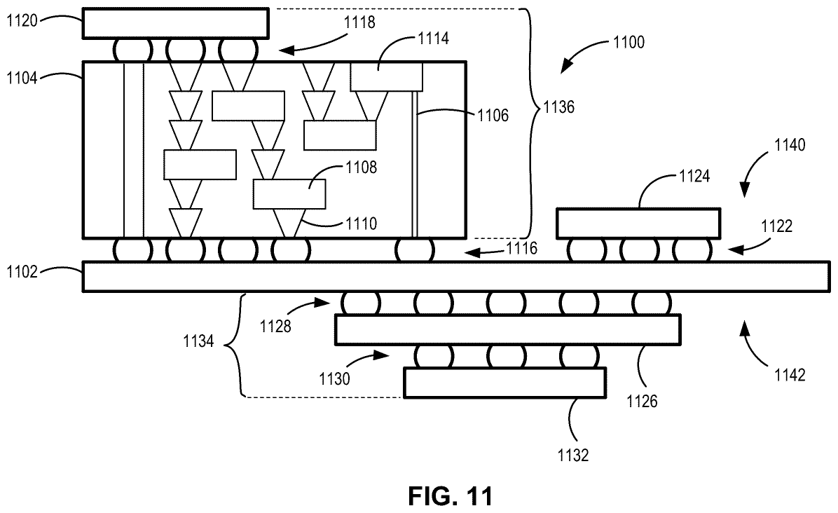

FIG. 11 is a cross-sectional side view of an IC device assembly 1100 that may include the IC package 100 disclosed herein. In some examples, the IC device assembly corresponds to the IC package 100. The IC device assembly 1100 includes a number of components disposed on a circuit board 1102 (which may be, for example, a motherboard). The IC device assembly 1100 includes components disposed on a first face 1140 of the circuit board 1102 and an opposing second face 1142 of the circuit board 1102; generally, components may be disposed on one or both faces 1140 and 1142. Any of the IC packages discussed below with reference to the IC device assembly 1100 may take the form of the example IC package 100 of FIG. 1.

In some examples, the circuit board 1102 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1102. In other examples, the circuit board 1102 may be a non-PCB substrate.

The IC device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), male and female portions of a socket, an adhesive, an underfill material, and/or any other suitable electrical and/or mechanical coupling structure.

The package-on-interposer structure 1136 may include an IC package 1120 coupled to an interposer 1104 by coupling components 1118. The coupling components 1118 may take any suitable form for the application, such as the forms discussed above with reference to the coupling components 1116. Although a single IC package 1120 is shown in FIG. 11, multiple IC packages may be coupled to the interposer 1104; indeed, additional interposers may be coupled to the interposer 1104. The interposer 1104 may provide an intervening substrate used to bridge the circuit board 1102 and the IC package 1120. The IC package 1120 may be or include, for example, a die (the die 902 of FIG. 9), an IC device (e.g., the IC device 1000 of FIG. 10), or any other suitable component. Generally, the interposer 1104 may spread a connection to a wider pitch or reroute a connection to a different connection. For example, the interposer 1104 may couple the IC package 1120 (e.g., a die) to a set of BGA conductive contacts of the coupling components 1116 for coupling to the circuit board 1102. In the example illustrated in FIG. 11, the IC package 1120 and the circuit board 1102 are attached to opposing sides of the interposer 1104; in other examples, the IC package 1120 and the circuit board 1102 may be attached to a same side of the interposer 1104. In some examples, three or more components may be interconnected by way of the interposer 1104.

In some examples, the interposer 1104 may be formed as a PCB, including multiple metal layers separated from one another by layers of dielectric material and interconnected by electrically conductive vias. In some examples, the interposer 1104 may be formed of an epoxy resin, a fiberglass-reinforced epoxy resin, an epoxy resin with inorganic fillers, a ceramic material, or a polymer material such as polyimide. In some examples, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through-silicon vias (TSVs) 1106. The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The IC device assembly 1100 may include an IC package 1124 coupled to the first face 1140 of the circuit board 1102 by coupling components 1122. The coupling components 1122 may take the form of any of the examples discussed above with reference to the coupling components 1116, and the IC package 1124 may take the form of any of the examples discussed above with reference to the IC package 1120.

The IC device assembly 1100 illustrated in FIG. 11 includes a package-on-package structure 1134 coupled to the second face 1142 of the circuit board 1102 by coupling components 1128. The package-on-package structure 1134 may include a first IC package 1126 and a second IC package 1132 coupled together by coupling components 1130 such that the first IC package 1126 is disposed between the circuit board 1102 and the second IC package 1132. The coupling components 1128, 1130 may take the form of any of the examples of the coupling components 1116 discussed above, and the IC packages 1126, 1132 may take the form of any of the examples of the IC package 1120 discussed above. The package-on-package structure 1134 may be configured in accordance with any of the package-on-package structures known in the art.

FIG. 12 is a block diagram of an example electrical device 1200 that may include one or more of the example IC package 100. For example, any suitable ones of the components of the electrical device 1200 may include one or more of the device assemblies 1100, IC devices 1000, or dies 902 disclosed herein, and may be arranged in the example IC package 100. A number of components are illustrated in FIG. 12 as included in the electrical device 1200, but any one or more of these components may be omitted or duplicated, as suitable for the application. In some examples, some or all of the components included in the electrical device 1200 may be attached to one or more motherboards. In some examples, some or all of these components are fabricated onto a single system-on-a-chip (SoC) die.

Additionally, in various examples, the electrical device 1200 may not include one or more of the components illustrated in FIG. 12, but the electrical device 1200 may include interface circuitry for coupling to the one or more components. For example, the electrical device 1200 may not include a display 1206, but may include display interface circuitry (e.g., a connector and driver circuitry) to which a display 1206 may be coupled. In another set of examples, the electrical device 1200 may not include an audio input device 1218 (e.g., microphone) or an audio output device 1208 (e.g., a speaker, a headset, earbuds, etc.), but may include audio input or output device interface circuitry (e.g., connectors and supporting circuitry) to which an audio input device 1218 or audio output device 1208 may be coupled.

The electrical device 1200 may include programmable circuitry 1202 (e.g., one or more processing devices). The programmable circuitry 1202 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1200 may include a memory 1204, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1204 may include memory that shares a die with the programmable circuitry 1202. This memory may be used as cache memory and may include embedded dynamic random access memory (eDRAM) or spin transfer torque magnetic random access memory (STT-MRAM).

In some examples, the electrical device 1200 may include a communication chip 1212 (e.g., one or more communication chips). For example, the communication chip 1212 may be configured for managing wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-1105 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1212 may operate in accordance with other wireless protocols in other examples. The electrical device 1200 may include an antenna 1222 to facilitate wireless communications and/or to receive other wireless communications (such as AM or FM radio transmissions).

In some examples, the communication chip 1212 may manage wired communications, such as electrical, optical, or any other suitable communication protocols (e.g., the Ethernet). As noted above, the communication chip 1212 may include multiple communication chips. For instance, a first communication chip 1212 may be dedicated to shorter-range wireless communications such as Wi-Fi or Bluetooth, and a second communication chip 1212 may be dedicated to longer-range wireless communications such as global positioning system (GPS), EDGE, GPRS, CDMA, WiMAX, LTE, EV-DO, or others. In some examples, a first communication chip 1212 may be dedicated to wireless communications, and a second communication chip 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display 1206 (or corresponding interface circuitry, as discussed above). The display 1206 may include any visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any device that generates an audible indicator, such as speakers, headsets, or earbuds.

The electrical device 1200 may include an audio input device 1218 (or corresponding interface circuitry, as discussed above). The audio input device 1218 may include any device that generates a signal representative of a sound, such as microphones, microphone arrays, or digital instruments (e.g., instruments having a musical instrument digital interface (MIDI) output).

The electrical device 1200 may include GPS circuitry 1216. The GPS circuitry 1216 may be in communication with a satellite-based system and may receive a location of the electrical device 1200, as known in the art.

The electrical device 1200 may include any other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include any other input device 1220 (or corresponding interface circuitry, as discussed above). Examples of the other input device 1220 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1200 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that include glass cores with increased the durability and reduce (e.g., minimize, etc.) risk for seware failures. Examples disclosed herein include glass cores with TGVs that protrude from the top of the glass core. Examples disclosed herein reduce the likelihood of stress concentration locations associated with the lateral stacking of materials with different coefficients of thermal expansion from forming at the entry of through glass vias. Examples disclosed herein prevent the deposition of the buffer material within the throughs holes, which reduces the thermal stress experienced by the glass core of package substrates and the likelihood of a seware failure occurring.

Further examples and combinations thereof include the following:

Example 1 includes a substrate for an integrated circuit package, the substrate comprising a glass core including a surface, and a copper through glass via (TGV) extending through the glass core, the TGV extending above the surface of the glass core.

Example 2 includes the substrate of any preceding example, including a buffer layer on the surface, the buffer layer surrounding a protrusion of the TGV above the surface.

Example 3 includes the substrate of any preceding example, wherein surface is a first surface and the buffer layer includes a second surface that is complimentary to the first surface.

Example 4 includes the substrate of any preceding example, wherein the TGV and the protrusion are integral.

Example 5 includes the substrate of any preceding example, wherein the TGV is a first TGV, and the substrate includes a second TGV, the glass core having a second region between the first TGV and the second TGV, and the first region and second region are substantially co-planar.

Example 6 includes the substrate of any preceding example, wherein the TGV is a first TGV, and the substrate includes a second TGV, the glass core having a second region between the first TGV and the TGV, and the second region having a curved shape.

Example 7 includes the substrate of any preceding example, wherein the curved shape is concave.

Example 8 includes a device comprising a semiconductor die, and a package substrate to support the semiconductor die, the package substrate including a glass core including a curved surface, and a copper through glass via (TGV) extending through the glass core, the TGV extending out of the curved surface.

Example 9 includes the device of any preceding example, including a buffer layer on the curved surface, the buffer layer surrounding a protrusion of the TGV above the curved surface.

Example 10 includes the device of any preceding example, wherein the protrusion has a length parallel to a thickness of the glass core, the length between 5% and 20% of the thickness of the glass core.

Example 11 includes the device of any preceding example, further including a build-up layer including an interconnect electrically coupled to the TGV, the buffer layer between the glass core and the build-up layer.

Example 12 includes the device of any preceding example, wherein the curved surface is a first curved surface, the protrusion is a first protrusion, the glass core further includes a second curved surface opposite the first curved surface, and the TGV includes a second protrusion extending from the second curved surface.

Example 13 includes the device of any preceding example, wherein the curved surface is concave.

Example 14 includes the device of any preceding example, wherein the curved surface is meniscus shaped.

Example 15 includes an apparatus comprising a semiconductor die, and a package substrate to support the semiconductor die, the package substrate including a glass core including an outer surface, and a build-up layer above the glass core, the build-up layer including an interconnect electrically coupled to the semiconductor die, and a copper through glass via (TGV) in a through hole of the glass core, the TGV including an end protruding above the outer surface, the end electrically coupled to the interconnect.

Example 16 includes the apparatus of any preceding example, further including a buffer layer between the build-up layer and the glass core, the buffer layer to at least partially surround the end.

Example 17 includes the apparatus of any preceding example, wherein the glass core has a first thickness adjacent to the TGV and a second thickness distal to the TGV, the first thickness greater than the second thickness.

Example 18 includes the apparatus of any preceding example, wherein the outer surface is substantially planar.

Example 19 includes the apparatus of any preceding example, wherein the outer surface is a first outer surface, the end is a first end, the glass core includes a second outer surface opposite the first outer surface, and the TGV includes a second end protruding from the second outer surface.

Example 20 includes the apparatus of any preceding example, wherein the TGV is in contact with the glass core adjacent to the outer surface.

Example 21 includes a method including creating a hole in a glass core of a package substrate, plating a through glass via (TGV) in hole of the package substrate, and processing at least one of the TGV or the glass core such that the TGV includes a protrusion extending from the glass core.

Example 22 includes the method of any preceding example, wherein the processing the at least one of the TGV or the glass core includes plasma dry etching the glass core, and wet etching the glass core.

Example 23 includes the method of any preceding example, wherein the wet etching includes applying sulfuric acid to glass core.

Example 24 includes the method of any preceding example, wherein the processing the at least one of the TGV or the glass core includes conducting a two-stage polishing process.

Example 25 includes the method of any preceding example, wherein the conducting a two-stage polishing process includes polishing the glass core with a copper slurry, and polishing the glass core with a silicon oxide slurry.

Example 26 includes the method of any preceding example, further including depositing a buffer layer on the glass core, the protrusion extending into the buffer layer.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A substrate for an integrated circuit package, the substrate comprising:
a glass core including a surface; and
a copper through glass via (TGV) extending through the glass core, the TGV extending above the surface of the glass core.

2. The substrate of claim 1, including a buffer layer on the surface, the buffer layer surrounding a protrusion of the TGV above the surface.

3. The substrate of claim 2, wherein surface is a first surface and the buffer layer includes a second surface that is complimentary to the first surface.

4. The substrate of claim 2, wherein the TGV and the protrusion are integral.

5. The substrate of claim 1, wherein the TGV is a first TGV, and the substrate includes a second TGV, the glass core having a second region between the first TGV and the second TGV, and the first region and second region are substantially co-planar.

6. The substrate of claim 1, wherein the TGV is a first TGV, and the substrate includes a second TGV, the glass core having a second region between the first TGV and the TGV, and the second region having a curved shape.

7. The substrate of claim 6, wherein the curved shape is concave.

8. A device comprising:
a semiconductor die; and
a package substrate to support the semiconductor die, the package substrate including:
a glass core including a curved surface; and
a copper through glass via (TGV) extending through the glass core, the TGV extending out of the curved surface.

9. The device of claim 8, including a buffer layer on the curved surface, the buffer layer surrounding a protrusion of the TGV above the curved surface.

10. The device of claim 8, wherein the protrusion has a length parallel to a thickness of the glass core, the length between 5% and 20% of the thickness of the glass core.

11. The device of claim 9, further including a build-up layer including an interconnect electrically coupled to the TGV, the buffer layer between the glass core and the build-up layer.

12. The device of claim 9, wherein the curved surface is a first curved surface, the protrusion is a first protrusion, the glass core further includes a second curved surface opposite the first curved surface, and the TGV includes a second protrusion extending from the second curved surface.

13. The device of claim 8, wherein the curved surface is concave.

14. The device of claim 11, wherein the curved surface is meniscus shaped.

15. An apparatus comprising:
a semiconductor die; and
a package substrate to support the semiconductor die, the package substrate including:
a glass core including an outer surface; and
a build-up layer above the glass core, the build-up layer including an interconnect electrically coupled to the semiconductor die; and
a copper through glass via (TGV) in a through hole of the glass core, the TGV including an end protruding above the outer surface, the end electrically coupled to the interconnect.

16. The apparatus of claim 15, further including a buffer layer between the build-up layer and the glass core, the buffer layer to at least partially surround the end.

17. The apparatus of claim 15, wherein the glass core has a first thickness adjacent to the TGV and a second thickness distal to the TGV, the first thickness greater than the second thickness.

18. The apparatus of claim 17, wherein the outer surface is substantially planar.

19. The apparatus of claim 15, wherein the outer surface is a first outer surface, the end is a first end, the glass core includes a second outer surface opposite the first outer surface, and the TGV includes a second end protruding from the second outer surface.

20. The apparatus of claim 15, wherein the TGV is in contact with the glass core adjacent to the outer surface.
